(19) United States
(12) Patent Application Publication
(10) Pub. No.: US 2007/0141233 A1
(43) Pub. Date: Jun. 21, 2007

(54) EB-PVD system with automatic melt pool height control

(75) Inventor: Kevin Walter Schlichting, Storrs, CT (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: United Technologies Corporation, Hartford, CT (US)

(21) Appl. No.: 11/313,315

(22) Filed: Dec. 21, 2005

(51) Int. Cl. C23C 16/52; C23C 14/30; C23C 16/00

(52) U.S. Cl. 427/8; 427/596; 118/726

(57) ABSTRACT

A system for applying a coating to a part has a crucible configured for receiving an ingot, a drive for feeding the ingot into the crucible, and an energy source for heating the ingot and melting a portion of the ingot such that it forms a molten pool and then evaporates. The system includes sensors that monitor the location of the molten pool within the crucible. The sensors are connected to a controller, which is also connected to the drive, such that the controller varies the feed rate of the ingot as a function of the sensed location of the molten pool.

### BACKGROUND OF THE INVENTION

The present invention relates generally to a system for applying a ceramic coating to a part. More particularly, the invention relates to an electron beam physical vapor deposition (EB-PVD) system for applying a coating, such as a thermal barrier coating, to a turbine part used in aircraft engines.

Electron beam physical vapor deposition is commonly used to apply a coating, metallic and/or ceramic, to aircraft engine parts that are used in the high-pressure turbine section of the engine. The coating may provide a thermal barrier from the hot gas stream and allows the turbines to run at higher gas path temperatures, which improves operating efficiency. The uniformity and quality of the coating is critical to the performance of the thermal barrier coating and consequently the durability of the aircraft engine part.

Electron beam physical vapor deposition is typically performed within a vacuum chamber. The coating material, commonly ceramic, is provided in solid form as an ingot and is fed into a cooled crucible having an annular passage. The part to be coated is rotated above the crucible. An electron beam heats the exposed end of the ceramic ingot, forming a molten pool that resides within the annular passage of the crucible. The material then vaporizes from the molten pool; the vapor fills the chamber and condenses upon the surface of the part to form a coating.

The distance between the part and the molten pool directly affects the quality of the coating. Therefore, it is critical that the height of the molten pool, in relation to its position within the crucible, remain constant so that the coating is uniformly applied to the part. The ceramic ingot does not melt at a constant rate. Consequently, it is not possible to maintain a constant melt pool height unless the feed rate of the ceramic ingot is variable. In current processes, the melt pool height is controlled manually by the operator. The operator visually monitors the melt pool height and adjusts the feed rate accordingly. As a result, coating variability exists between operators, as well as between coating runs.

There is a need for an automated system that can maintain the melt pool height at a constant value, thus keeping the part-to-pool distance constant and reducing the variability in the coating process.

### BRIEF SUMMARY OF THE INVENTION

The present invention relates to a system for applying a coating to a part, including a crucible configured for receiving an ingot, a drive that feeds the ingot into the crucible, and an energy source that melts a portion of the ingot, forming a molten pool and then evaporating. Sensors monitor the location of the molten pool within the crucible, and are connected to a controller. The controller varies the feed rate of the ingot as a function of the sensed location of the molten pool.

### BRIEF DESCRIPTION OF THE DRAWINGS

FIG. 1 is a diagram of a system for applying a coating using EB-PVD, including the molten pool height control of the present invention.

FIG. 2 is a perspective view of an exemplary crucible used in the system shown in FIG. 1.

FIG. 3 is a diagram, in cross-section, showing the crucible and ingot used in the EB-PVD system of FIG. 1.

### DETAILED DESCRIPTION

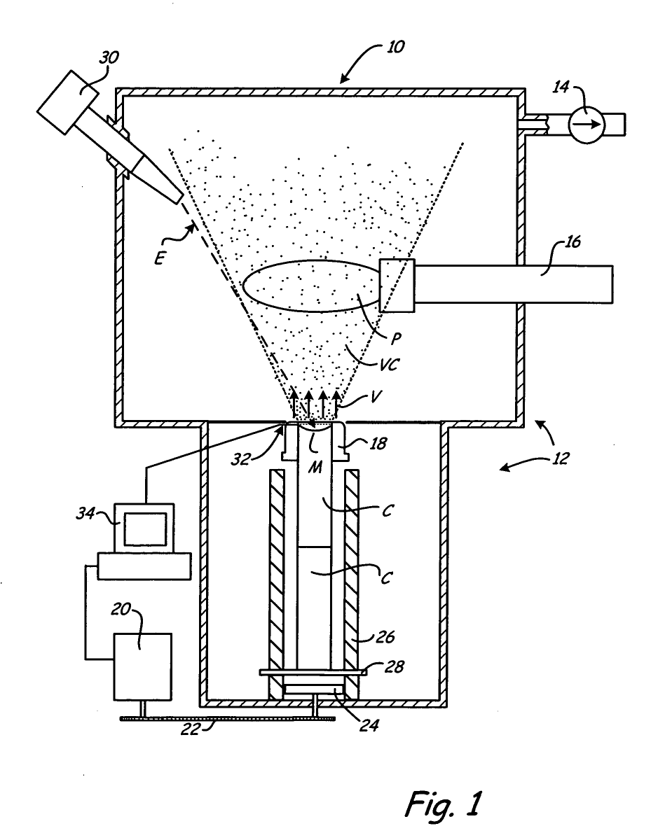

FIG. 1 is a diagram of EB-PVD system 10 for applying a coating to part P. System 10 includes closed chamber 12, vacuum source 14, rotating shaft 16, crucible 18, motor 20, chain drive 22, gear 24, screw drive 26, platform 28, electron beam gun 30, temperature sensors 32 and controller 34. While the illustrated embodiment refers to the application of a ceramic coating, it is to be understood that the invention is not so limited.

Part P is shown inside chamber 12 and is supported by rotating shaft 16. Ceramic ingots C are fed upward into crucible 18 by a drive system including motor 20, chain drive 22, gear 24, screw drive 26 and platform 28. As platform 28 is driven upward, it raises ceramic ingots C upward and into crucible 18.

Electron beam gun 30 generates electron beam E which is directed onto an upper end portion of ceramic ingot C, causing a portion of ceramic ingot C to melt and form molten ceramic pool M. Vapors V evaporate from molten ceramic pool M, forming vapor cloud VC and then condensing onto part P to form a coating on part P.

In this embodiment, electron beam E is used to melt the upper end of ceramic ingot C. However, it is recognized that various other energy sources could be used to heat the ceramic ingot to form a molten pool.

Temperature sensors 32 monitor molten ceramic pool M, as described in more detail below, and are connected to controller 34 to provide signals indicating the height of molten ceramic pool M within crucible 18. Controller 34 is also connected to motor 20 to control the feed rate of ceramic ingot C into crucible 18 as a function of sensed molten pool height.

The coating, formed from vapors V from molten ceramic pool M of ceramic ingot C, is a thermal barrier coating. Its general purpose is to reduce heat flow into the part on which it is coated (which may also be cooled via cooling air flowing through internal passages in the part), and thus protect the part in high temperature environments. Turbine components used in aircraft engines are subject to gas temperatures of up to 2500-3000° F. High gas temperatures are crucial for improving the operating efficiency of the engine.

Due to the high operating temperatures, the coating material must have a low thermal conductivity. A commonly used ceramic material, which is well known in the art, is yttria stabilized zirconia (YSZ). Prior to applying the ceramic coating, another layer, such as a metallic bond layer, may be coated onto part P.

The EB-PVD system of FIG. 1 shows a stack of two ceramic ingots being fed into a single crucible. However, it is recognized that a system that uses multiple crucibles and ingots is within the scope of this invention.

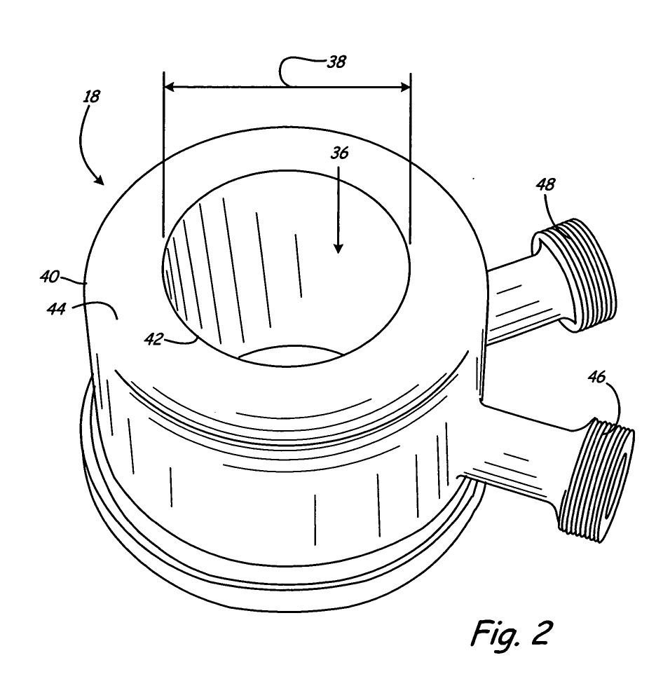

FIG. 2 is a perspective view of an exemplary crucible used in EB-PVD system 10 shown in FIG. 1. Crucible 18 is preferably made from copper and is generally cylindrical in shape, although it is understood that crucible 18 may be made from other materials and formed into other shapes. Crucible 18 has annular passage 36, which defines diameter 38. Diameter 38 is roughly equal to or slightly larger than the diameter of ceramic ingot C such that ceramic ingot C extends into annular passage 36.

Crucible 18 has outer wall 40, inner wall 42, hollow interior 44 (which defines the space between outer wall 40 and inner wall 42), water inlet 46, and water outlet 48. Inlet 46 is configured so that cooling water may be circulated through hollow interior 44 of crucible 18. Outlet 48 is used to transport the cooling water out of hollow interior 44.

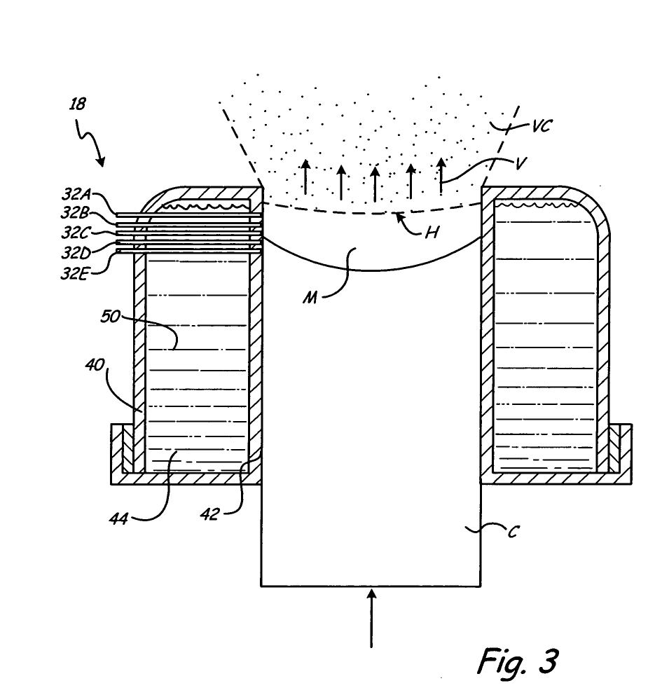

FIG. 3 is a cross-sectional view of the crucible used in the system shown in FIG. 1, with ceramic ingot C being fed into crucible 18 through annular passage 36. FIG. 3 shows outer wall 40, inner wall 42, cooling water 50 circulating through hollow interior 44, and temperature sensors 32A-32E. Molten ceramic pool M is formed when electron beam E bombards the upper end of ceramic ingot C, causing a portion of ingot C to melt. Melt pool height H represents the vertical position of the upper surface of molten ceramic pool M within annular passage 36 of crucible 18.

Electron beam E moves back and forth over the upper end of ceramic ingot C to form a raster pattern on ingot C. Electron beam gun 30 is programmable to form various patterns on ingot C, in addition to or as an alternative to moving back and forth over ingot C. The contact of electron beam E with ceramic ingot C causes ingot C to melt, forming molten ceramic pool M. As shown in FIG. 3, molten ceramic pool M is somewhat meniscus-shaped due to contact with cooled inner wall 42 of crucible 18.

The burn rate or melt rate of ceramic ingot C is variable as a function, in part, of the raster pattern of electron beam E on ingot C and the variability in the power of electron beam gun 30 as it ages. Due to the variability of the melt rate of ceramic ingot C, the evaporation rate of vapors V from molten ceramic pool M is also variable. If the evaporation rate increases, then the molten pool surface (i.e. melt pool height H) will move downward within crucible 18. If the evaporation rate decreases, then the molten pool surface will move upward within crucible 18, since ceramic ingot C is being continuously fed into crucible 18. In either scenario—whether the molten pool surface moves up or down—as melt pool height H changes, the part-to-pool distance will change, thus varying the consistency of the coating applied to part P.

To maintain a constant melt pool height within crucible 18, the feed rate of ingot C must be continuously adjusted to compensate for the variability in the melt rate of ingot C. Melt pool height H can be monitored visually by an operator, who adjusts the motor as needed to vary the feed rate in order to eliminate or minimize the changes in the melt pool height. However, this introduces variability between operators and even between coating runs with the same operator. By automating the process using signals from temperature sensors 32A-32E to control motor 20, and therefore the feed rate of ceramic ingot C into crucible 18, it is possible to better maintain a constant melt pool height.

In the embodiment shown in FIG. 3, temperature sensors 32A-32E are a plurality of thermocouples that are inserted into crucible 18 through outer wall 40 and contact inner wall 42. Thermocouples 32A-32E are spaced from each other vertically along inner wall 42. Each of the thermocouples 32A-32E determines the temperature at a particular location along inner wall 42. Based on the differences in temperature sensed by thermocouples 32A-32E, melt pool height H can be determined by controller 34 and used to control speed of motor 20.

In this particular embodiment, five thermocouples 32A-32E are shown; however, it is recognized that more or less thermocouples are within the scope of this invention. There must be enough thermocouples to vertically cover the depth of molten ceramic pool M and solid ingot C, and be spaced close enough to determine the location of the interface between solid ingot C and molten ceramic pool M. The number of thermocouples and the spacing of the thermocouples used will depend on the control limits for maintaining a constant melt pool height within crucible 18. As the control limits are tightened, additional thermocouples will be needed. The type of thermocouple used will determine the accuracy of the temperature reading.

Temperature sensors 32A-32E are connected to controller 34, which may be a computer having a computer program that determines a location of molten ceramic pool M based upon a temperature gradient along inner wall 42 of crucible 18. Based on the temperature readings of each of sensors 32A-32E, controller 34 determines melt pool height H. To maintain melt pool height H at a constant location vertically within crucible 18, controller 34 adjusts the speed of motor 20, which changes the feed rate of ceramic ingot C into crucible 18. If melt pool height H begins to rise within crucible 18 because less vapors are evaporating from molten ceramic pool M, then controller 34 will decrease the feed rate. On the other hand, if controller 34 determines melt pool height H beginning to fall within crucible 18 because more vapors are evaporating from molten ceramic pool M, then controller 34 will increase the feed rate.

Although the present invention has been described with reference to preferred embodiments, workers skilled in the art will recognize that changes may be made in form and detail without departing from the spirit and scope of the invention.

1. A system for applying a coating to a part, the system comprising:
a crucible configured for receiving an ingot;
a drive that feeds the ingot into the crucible at a feed rate;
means for heating the ingot, causing a portion of the ingot to melt, forming a molten pool and then evaporating;
a plurality of sensors for monitoring a location of the molten pool within the crucible; and
a controller that controls the feed rate as a function of the sensed location of the molten pool.

2. The system of claim 1 wherein the controller varies the feed rate so that the location of the molten pool within the crucible is substantially constant.

3. The system of claim 1 wherein the means for heating is an electron gun for generating an electron beam that heats the ingot.

4. The system of claim 1 wherein the plurality of sensors are a plurality of thermocouples.

5. The system of claim 4 wherein the plurality of thermocouples reside inside the crucible, adjacent an inner wall of the crucible.

6. The system of claim 1 wherein the drive is a motor connected to a screw drive that raises the ingot up to feed the ingot into the crucible.

7. The system of claim 1 wherein the controller is a computer having a computer program that determines the location of the molten pool in the crucible based on a temperature gradient along an inner wall of the crucible.

8. The system of claim 1 wherein the crucible has an annular passage and the ingot is fed through the annular passage.

9. The system of claim 1 wherein the crucible is made of copper.

10. The system of claim 1 wherein cooling water is circulated through an internal space of the crucible between an inner wall and an outer wall.

11. A system for applying a coating to a part, the system comprising:
a crucible configured for receiving an ingot;
a drive that feeds the ingot into the crucible at a feed rate;
an electron beam gun generating an electron beam that contacts the ingot, causing a portion of the ingot to melt, forming a molten pool and then evaporating, wherein the molten pool has a melt pool height defining a location of the molten pool vertically along an inner wall of the crucible;
temperature sensors that determine a temperature reading at various points along the molten pool and the ingot; and
a controller, connected to the drive and the temperature sensors, for determining the melt pool height based on the temperature readings and controlling the drive as a function of the melt pool height.

12. The system of claim 11 wherein the controller is configured to adjust the feed rate of the ingot such that the melt pool height remains substantially constant.

13. The system of claim 11 wherein the temperature sensors are a plurality of thermocouples inserted through an outer wall of the crucible to contact the inner wall of the crucible.

14. The system of claim 11 wherein the drive includes a motor, and the controller controls a speed of the motor as a function of the melt pool height.

15. A method of applying a coating to a part, the method comprising the steps of:
feeding an ingot into a crucible;
heating a portion of the ingot, wherein the ingot forms a molten pool and then evaporates;
coating the part with vapors that evaporate from the molten pool;
sensing a temperature gradient inside the crucible; and
controlling a feed rate of the ingot into the crucible based on the temperature gradient inside the crucible.

16. The method of claim 15 and further comprising:
cooling the crucible using circulating water that passes between an inner wall and an outer wall of the crucible.

17. The method of claim 15 wherein sensing the temperature gradient inside the crucible is performed by a plurality of thermocouples.

18. The method of claim 15 and further comprising:
relaying the temperature gradient to a controller that determines a location of the molten pool within the crucible based on the temperature gradient.

19. The method of claim 18 wherein the feed rate of the ingot is variable and is controlled to maintain the location of the molten pool substantially constant.

20. The method of claim 15 wherein heating the portion of the ingot is performed by an electron beam.
